(19) United States
(12) Patent Application Publication
(10) Pub. No.: US 2009/0079332 A1
(43) Pub. Date: Mar. 26, 2009

(54) LIGHT EMITTING DEVICE

(76) Inventors: Hongmo Koo, Gumi-city (KR); Daeyang Oh, Seoul (KR)

Correspondence Address: KED & ASSOCIATES, LLP, P.O. Box 221200, Chantilly, VA, 20153-1200, US

(21) Appl. No.: 11/949,913

(22) Filed: Dec. 4, 2007

(30) Foreign Application Priority Data
Sep. 21, 2007 (KR) 10-2007-0097020

(51) Int. Cl. H01L 27/28

(52) U.S. Cl. 313/504

(57) ABSTRACT

A light-emitting device includes a substrate with a thin film transistor, an insulating film on the substrate that includes a via hole exposing the thin film transistor, a first electrode on the insulating film and connected to the thin film transistor, an emitting layer on the first electrode, and a second electrode on the emitting layer and including a non-conductive layer and a transparent conductive layer sequentially disposed over the emitting layer. A thickness of the first electrode is a predetermined number of times greater than a thickness of the emitting layer, and a thickness of the second electrode is a predetermined number of times greater than the thickness of the emitting layer.

This application claims the benefit of Korean Patent Application No. 10-2007-0097020 filed in Korea on 21. Sep. 2007, which is hereby incorporated by reference.

### BACKGROUND

1. Field

One or more embodiments described herein relate to a display device.

2. Background

Flat panel displays that emit light based on the formation of excitons have wide viewing angles, high response speed, and high contrast. They are also light-weight and are able to display large numbers of colors. In spite of these advantages, flat panel displays have drawbacks relating to power consumption, emission efficiency, and reliability.

### BRIEF DESCRIPTION OF THE DRAWINGS

FIGS. 1a-1e are cross-sectional views of one embodiment of a light-emitting device.

FIGS. 2a and 2b are cross-sectional views of another embodiment of a light-emitting device.

FIGS. 3A to 3C are diagrams showing various implementations of a color image display method in an organic light emitting device according to one or more exemplary embodiments.

### DETAILED DESCRIPTION

Certain types of light-emitting devices emit light based on excitons, which are created when electrons and holes are injected into and combined within an emitting layer. When the excitons drop from an excited state to a base or stable state, light is generated. In the case of a flat panel display, multiple light-emitting devices are provided in the form of a matrix to generate an image.

In terms of structure, an organic light-emitting device is generally formed from a single layer or a plurality of organic layers (or inorganic layers) stacked between an anode electrode (e.g., a hole injection electrode) and a cathode electrode (e.g., an electron injection electrode). The organic or inorganic layer(s) emit light when a voltage is applied to the electrodes.

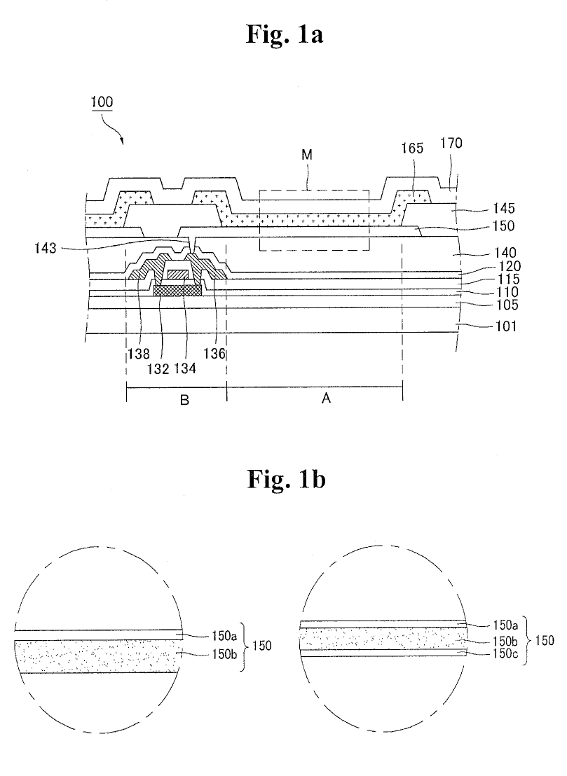

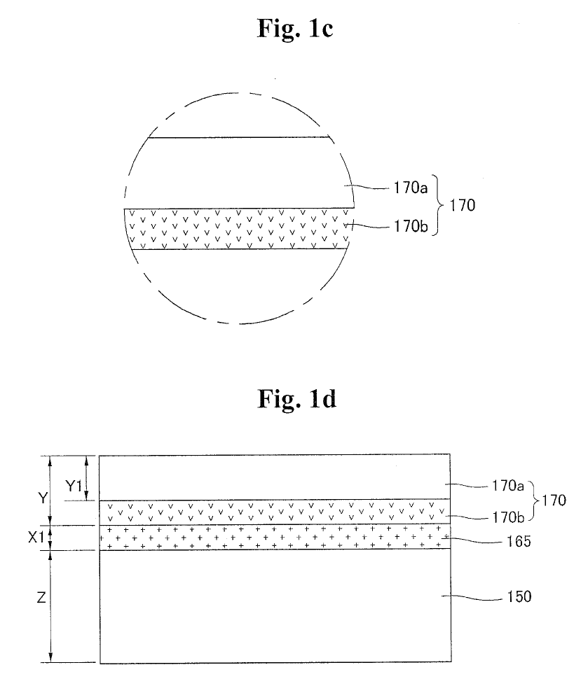

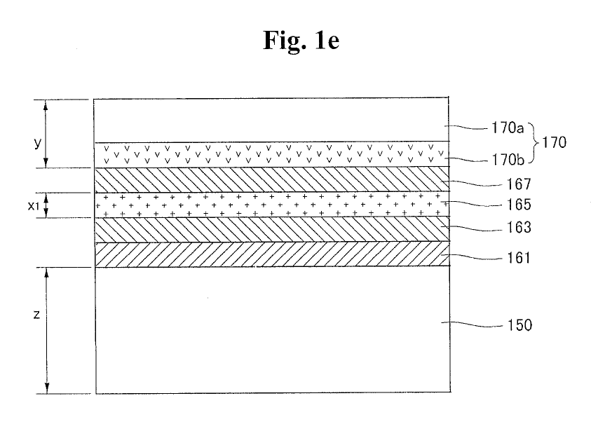

FIGS. 1a to 1e are cross-sectional views of one embodiment of a light-emitting device, which includes a substrate 101, a buffer layer 105, a thin film transistor, first to fifth insulating films, a first electrode 150, an emitting layer 165, a second electrode 170, as well as other layers.

The substrate 101 may be formed from a transparent glass or a plastic material.

The buffer layer 105 is formed on the substrate and serves to prevent impurities from entering the device, for example, from the substrate during a subsequent manufacturing process. The buffer layer 105 may be made of SiNx, SiO2 or SiOxNx.

The thin film transistor includes a gate electrode 134, a source electrode 138, a drain electrode 136, and a semiconductor layer 132, and preferably has a coplanar structure, e.g., the thin film transistor can have a top gate structure in which the gate electrode is disposed over the semiconductor layer. The semiconductor layer may be disposed on the buffer layer to form a channel region, and may be made of crystalline, polycrystalline or amorphous material. One representative material that may be used silicon (Si), but other materials may be used if desired. Moreover, the thin film transistor may have a structure different from that shown in FIG. 1a in alternative embodiments.

A first insulating film 110 (which may be referred to as a gate insulating film) is disposed on the buffer layer 105 on which the semiconductor layer is formed. The first insulating film may be made of a SiNx or SiO2 material, but is not limited thereto. The gate insulating film may serve to isolate the gate, source, and drain electrodes of the thin film transistor from one another.

The gate electrode 134 may be formed on the first insulating film at a location that corresponds to semiconductor layer 132. The gate electrode can turn on/off the thin film transistor in response to a data voltage supplied from a data line (not shown).

A second insulating film 115, which may be referred to as an interlayer insulating film, is formed on the first insulating film on which the gate electrode is formed. The second insulating film may be made of a SiNx or SiO2 material, but is not limited thereto.

Contact holes for forming source electrode 138 and drain electrode 136, which are connected to semiconductor layer 132, may be formed on first insulating film 110 and second insulating film 115. The source electrode and drain electrode are connected to the semiconductor layer through the contact holes and can be projected upwardly from the second insulating film 115 through the contact holes.

The gate electrode 134, source electrode 138, and drain electrode 136 may have a stack structure comprising one or more of chrome (Cr), aluminum (Al), molybdenum (Mo), silver (Ag), copper (Cu), titanium (Ti), tantalum (Ta) or one of their alloys.

A third insulating film 120 (which may serve as an inorganic passivation film) may be formed on the thin film transistor and second insulating film 115. The inorganic passivation film can provide a passivation effect for the semiconductor layer as well as an external light-shielding effect.

A fourth insulating film 140 (which may be referred to as a planarization film) may be formed over the substrate over which the third insulating film 120 has been formed. A via hole through which a part of the thin film transistor is exposed may be formed in the fourth insulating film 140, e.g., via hole 143 through which a part of drain electrode 136 extends or contacts may be formed in third insulating film 120 and fourth insulating film 140. The fourth insulating film can be formed to protect the thin film transistor and to provide insulation between elements and signal lines. The fourth insulating film may be made of benzocyclobutene, polyimide, or acrylic resin, or a combination thereof, but is not limited to these materials.

The first electrode 150 may be formed on fourth insulating film 140 and may be electrically connected to drain electrode 136 of the thin film transistor through via hole 143, formed in the fourth insulating film 140 and the third insulating film 120. The first electrode may operate as an anode electrode, and as such may receive a voltage from the thin film transistor and supply the emitting layer 165 with holes. The light-emitting device in accordance with this embodiment, therefore, has a top-emission structure.

FIG. 1b is an enlarged view of the first electrode 150 in FIG. 1a. As shown, the first electrode is disposed on fourth insulating film 140 and may comprise two electrodes: a reflective electrode 150b connected to the thin film transistor through via hole 143 and a first transparent electrode 150a on the reflective electrode. The reflective electrode may be electrically connected to drain electrode 136 of the thin film transistor, and the first transparent electrode may be electrically connected to the reflective electrode.

In this top-emission structure, when light generated from the emitting layer 165 goes towards the first electrode 150, reflective electrode 150b disposed on a lower side of the first transparent electrode may serve to send light, that has reached the first electrode, to the second electrode. The reflective electrode 150b may be made of a material with a good reflectance such as but not limited to silver (Ag), aluminum (Al), or nickel (Ni).

In an alternative arrangement, the first electrode may also include a second transparent electrode 150c connected to drain electrode 136 of the thin film transistor through via hole 143. In this arrangement, the reflective electrode 150b and first transparent electrode 150a are formed over the second transparent electrode 150c.

With the second transparent electrode 150c formed below reflective electrode 150b, contact ability can be improved when the first electrode is connected to the thin film transistor. The first transparent electrode 150a and second transparent electrode 150c may, for example, be made of ITO or IZO.

Referring back to FIG. 1a, a fifth insulating film 145 (which may be referred to as a pixel definition film) is formed on the fourth insulating film 140 and first electrode 150. An opening through which a part of the first electrode 150 is exposed to define a light-emitting region A may be formed in the fifth insulating film. The fifth insulating film may be made of benzocyclobutene, polyimide, or acrylic resin, but is not limited thereto.

The emitting layer 165 is disposed on first electrode 150 and can receive holes from the first electrode.

The second electrode 170 may be disposed in opposing relation to the first electrode, with the emitting layer 165 therebetween. The second electrode may be a cathode electrode. In operation, emitting layer 165 generates excitons based on the combination of holes and electrons received from the first and second electrodes. When the excitons fall to a base or stable state, light is radiated in a forward direction to display an image.

FIG. 1c is an enlarged view of the second electrode 170 shown in FIG. 1a. As shown, the second electrode may include two electrodes: a non-conductive layer 170b disposed on emitting layer 165 and a transparent conductive layer 170a on the non-conductive layer 170b.

The transparent conductive layer 170a may be made of ITO or IZO, but is not limited thereto. For example, the materials of the transparent conductive layer can be selected from oxides, nitrides, or sulfides. Examples of metal oxides include indium tin oxide, aluminum-, and indium doped zinc oxide, tin oxide, magnesium-indium-oxide, nickel tungsten oxide, and cadmium tin oxide. Examples of nitrides include gallium nitride, indium nitride, or mixtures of Group III sulfide includes Group II sulfides such ZnS. In some cases, a thin metal layer may be used as the outer layer to form a semi-transparent cathode. Examples of metals include gold, silver aluminum, nickel, palladium, and platinum. The second electrode may include the transparent conductive layer so that it can radiate light more easily in the top-emission structure.

The work function of the transparent conductive layer is preferably relatively high. To compensate for this, non-conductive layer 170b may be formed below the transparent conductive layer and may be made of a fluorine (F)-based compound. The fluorine (F)-based compound may include, for example, lithium fluoride (LiF) or magnesium fluoride (MgF) but it is not limited thereto. Furthermore, the non-conductive layer formed from the above material can significantly prevent corrosion.

Lithium fluoride (LiF) may be preferably because it has strong ion bond characteristics. In general, bonds between chemical elements can be classified into covalent bonds and ion bonds. They can be classified according to an absolute value of a difference in electrongativity of respective chemical elements. In general, when the absolute value of the difference in the electrongativity of respective chemical element is 1.67 or more, it can be said that bonds between the chemical elements are ion bonds.

In lithium fluoride (LiF), the electrongativity of lithium is 3.98 and the electrongativity of fluorine is 0.98. Thus, the absolute value of a difference in the electrongativity of lithium and fluorine becomes 3. The result shows that lithium fluoride (LiF) has very strong ion bonds. In ion bonds, strong bonds form a dipole within the bonds. In other words, lithium fluoride (LiF) is a material having strong ion bonds to form a dipole, and a distance between atoms of the two chemical elements is very close.

Lithium fluoride (LiF) forms a strong dipole and thus increases electron injection into the emitting layer 165. Consequently, with this material, emission efficiency can be improved and a driving voltage can be lowered.

On the other hand, a lithium complex (Liq) has a weaker bonding force than lithium fluoride (LiF), but it may be used as the material of the electron injection layer. Accordingly, it can increase electron injection and improve emission efficiency.

FIG. 1d is an enlarged view of a portion “M” in FIG. 1a, and FIG. 1e is a view further illustrating the respective function layers in FIG. 1d. In the light-emitting device, the ratio of the thickness of each electrode and the thickness of the emitting layer 165 has an close relationship in terms of emission efficiency and power consumption of devices, and process efficiency.

Referring to FIGS. 1d and 1e, in light-emitting device 100 the first electrode 150, emitting layer 165, and second electrode 170 are sequentially formed over the fourth insulating film. Furthermore, they may have a constant thickness (width).

According to one embodiment, a thickness Z of first electrode 150 may be 4.2 to 7.7 times greater than a thickness X1 of the emitting layer 165. This range is preferable because, in a top-emission structure, when the thickness of the first electrode 150 is less than 4.2 times that of the emitting layer, electrical characteristics of the light-emitting device are degraded and power consumption can be increased. Moreover, when the thickness of the first electrode is greater than 7.7 times that of the emitting layer, the ratio of electrons provided from the second electrode is not identical to the ratio of holes provided from the first electrode; that is, the ratio of charges is unbalanced. Thus, the formation of excitons may become irregular.

The thickness Y of the second electrode 170 may be 0.6 to 7.3 times greater than the thickness X1 of the emitting layer 165. This range may be preferable because, when the thickness of the second electrode is less than 0.6 times that of the emitting layer, electrical characteristics of the light-emitting device are degraded, so that power consumption can be increased or leakage current may be generated. Also, in the second electrode, transparent conductive layer 170a may be made of a transparent material such as ITO or IZO. The above materials may be degraded only partially at the time of thin deposition when their surface are deposited roughly and thinly, so that dark spots can be generated near places where only the materials are degraded. There may also be a problem in controlling the thickness when etching the electrode.

When the thickness of the second electrode 170 is greater than 7.3 times that of the emitting layer, transmittance of light is decreased, which can make light difficult to pass the second electrode. Further, there occurs a problem in that an etching time of the electrode increases in terms of process. Furthermore, when stress caused by heat is great and the second electrode is thickly deposited in an opposite direction to the substrate, the second electrode may be bent to one side due to the stress.

The thickness Y1 of the transparent conductive layer 170 may be 0.2 to 6.7 times greater than the thickness X1 of the emitting layer 165.

A light-emitting device according to this embodiment may demonstrate good emission efficiency and uniformity of light output from sub pixels when first electrode 150, emitting layer 165, and second electrode 170 have the above-described numerical values. Further, a light-emitting device constructed in this manner can have low power consumption and high emission efficiency, and it is also efficient in terms of process such as etching.

In addition to the foregoing features, a hole injection layer 161 and a hole transfer layer 163 may be sequentially formed over the first electrode 150, and more specifically between the first electrode and emitting layer 165. The hole injection layer and hole transfer layer can make smooth the injection and transfer of holes from the first electrode 150 to the emitting layer 165.

Additionally, an electron transfer layer 167 may be formed on emitting layer 165, and more specifically between the emitting layer and the second electrode 170 These layers can make smooth the transfer of electrons from the second electrode 170 to the emitting layer 165.

In terms of materials, one or more of the emitting layer 165, hole injection layer 161, hole transfer layer 163, or electron transfer layer 167 may be formed from an organic material or an inorganic material.

The hole injection layer 161 formed from organic material may also include an inorganic material. Further, the inorganic material may be a metal compound such as but not limited to alkali metal or alkali earth metal. Examples of metal compounds comprising an alkali or alkali earth metal include LiF, NaF, KF, RbF, CsF, FrF, BeF2, MgF2, CaF2, SrF2, BaF2, and RaF2.

Generally, the mobility of holes is generally 10 times faster than the mobility of electrons. Thus, the amount of holes injected into emitting layer 165 is different from the amount of electrons injected into the emitting layer. As a result, emission efficiency of the light-emitting device may be degraded.

In accordance with the present embodiment, an inorganic material may be included to lower the highest level of a valence band of the hole injection layer 161, compared to an organic hole injection layer formed only of organic material. Thus, by including an inorganic material in hole injection layer 161 that is also formed from organic material, the mobility of holes injected from the first electrode 150 to the emitting layer 165 will be lowered, so that a more balanced amount of holes and electrons are transferred to the emitting layer. Accordingly, there is an advantage in that emission efficiency can be improved in accordance with the present embodiment.

The emitting layer may be made from a fluorescent material or a phosphor material. Because phosphor material has an increased internal quantum efficiency, en embodiment which uses phosphorescent material will now be described as an example.

An emitting layer that emits red light may comprise a host material made of CBP (carbazole biphenyl) or mCP(1,3-bis(carbazol-9-yl)), and may be formed from a phosphor material that includes a dopant comprising one or more of PlQIr(acac)(bis(1-phenylisoquinoline)acetylacetonate iridium), PQIr(acac)(bis(1-phenylquinoline)acetylacetonate iridium), PQIr(tris(1-phenylquinoline)iridium), or PtOEP(octaethylporphyrin platinum). An iridium-based transfer metal compound may also be used such as iridium(III)(2-(3-methylpheny)-6-(methylquinolinato-N,C2′)(2,4-pentanedionate-O,O), platinum porphyrin and so on. Alternatively, a red emitting layer may be formed from a fluorescent material comprising PBD:Eu(DBM)3(Phen) or perylene.

In the case where the emitting layer emits red light, a highest occupied molecular orbital of the host material may range from 5.0 to 6.5 eV, and a lowest unoccupied molecular orbital of the host material may range from 2.0 to 3.5 eV. A highest occupied molecular orbital of the dopant material may range from 4.0 to 6.0 eV, and a lowest unoccupied molecular orbital of the dopant material may range from 2.4 to 3.5 eV.

An emitting layer that emits blue light may comprise a host material such as CBP or mCP, and may be formed from a phosphor material that includes a dopant material comprising (4,6-F2 ppy)2Irpic. The dopant material may include an iridium-based transfer metal compound, such as (3,4-CN)3Ir, (3,4-CN)2Ir (picolinic acid), (3,4-CN)2Ir(N3), (3,4-CN)2Ir(N4), or (2,4-CN)3Ir. Alternatively, the blue emitting layer may be formed from a fluorescent material such as but not limited to spiro-DPVBi, spiro-6P, distylbenzene (DSB), distrylarylene (DSA), or PFO-based polymers, or a PPV-based polymer.

In the case where the emitting layer emits blue light, a highest occupied molecular orbital of the host material may range from 5.0 to 6.5 eV, and a lowest unoccupied molecular orbital of the host material may range from 2.0 to 3.5 eV. A highest occupied molecular orbital of the dopant material may range from 4.5 to 6.0 eV, and a lowest unoccupied molecular orbital of the dopant material may range from 2.0 to 3.5 eV.

An emitting layer that emits green light may comprise a host material such as CBP or mCP, and may be formed from a phosphor material that includes a dopant material comprising Ir(ppy)3(fac tris(2-phenylpyridine)iridium). The dopant material may also include tris(2-:pyridine)Ir(III) or the like. Alternatively, the green emitting layer may be formed from a fluorescent material comprising Alq3(tris(8-hydroxyquinolino)aluminum).

In the case where the emitting layer emits green light, a highest occupied molecular orbital of the host material may range from 5.0 to 6.5 eV, and a lowest unoccupied molecular orbital of the host material may range from 2.0 to 3.5 eV. A highest occupied molecular orbital of the dopant material may range from 4.5 to 6.0 eV, and a lowest unoccupied molecular orbital of the dopant material may range from 2.0 to 3.5 eV.

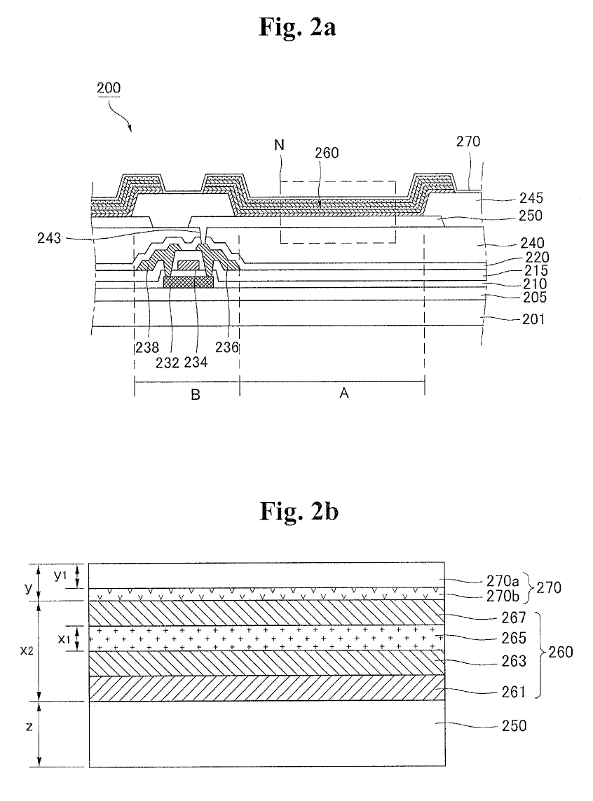

FIGS. 2a and 2b are cross-sectional views of another embodiment of a light-emitting device. This embodiment includes a light-emitting device 200 that is similar to that of FIG. 1a, except that a hole injection layer 261, a hole transfer layer 263, and an electron transfer layer 267 may be sequentially formed with an emitting layer 265 between a first electrode 250 and a second electrode 270.

The second electrode 270 may include two layers: a non-conductive layer 270b formed on electron transfer layer 267 and a transparent conductive layer 270a formed on non-conductive layer 270b. Transparent conductive layer 270a may be made of ITO or IZO, but is not limited thereto. The second electrode 270 may include the transparent conductive layer 270a so that light can be radiated more easily in the top-emission structure.

Further, the work function of the transparent conductive layer 270a may be relatively high. To compensate for this, non-conductive layer 270b may be formed below the transparent conductive layer 270a. The non-conductive layer 270b may be formed from fluorine (F)-based compound. Examples of the fluorine (F)-based compound include but are not limited to lithium fluoride (LiF) and magnesium fluoride (MgF). Furthermore, the non-conductive layer formed from the above material can significantly prevent corrosion.

Use of a fluoride-abed compound may be desirable because it has a strong dipole layer and a low work function, and can therefore become a good material for enabling the second electrode 270 to inject electrons into the emitting layer 265.

FIG. 2b is an enlarged view of a portion “N” of FIG. 2a. In this enlarged view, a thickness Z of the first electrode 250 may be 0.6 to 0.79 times greater than a thickness X2 of a function layer 260. This range may be preferable because, in a top-emission structure, when the thickness of the first electrode 250 is less than 0.6 times that of the function layer, electrical characteristics of the light-emitting device are degraded and power consumption can be increased accordingly.

When the thickness of the first electrode 250 is greater than 0.79 times that of the function layer 260, a ratio of electrons supplied from the second electrode is not identical to that of holes supplied from the first electrode. Consequently, the amount of holes and electrodes transferred into the emitting layer is not balanced and irregular formation of excitons may result.

The thickness Y of the second electrode 270 may be 0.09 to 0.76 times greater than the thickness X2 of the function layer 260. This range may be preferable because, when the thickness of the second electrode 270 is less than 0.09 times that of the function layer, electrical characteristics of the light-emitting device are degraded, power consumption is increased and leakage current can be generated. Further, when etching the electrode, thickness control may become difficult. Transparent conductive layer 270a of the second electrode may be made of a transparent material such as ITO or IZO. The above materials may be degraded only partially at the time of thin deposition when their surface are deposited roughly and thinly, so that dark spots can be generated near places where only the materials are degraded.

When the thickness of the second electrode 270 is 0.76 times greater than that of the function layer 260, transmittance of light is decreased which can make light difficult to pass the second electrode. Further, there occurs a problem in that an etching time of the electrode increases in terms of process. Furthermore, when stress caused by heat is great and the second electrode is thickly deposited in opposing relation to the substrate, the second electrode may be bent to one side due to the stress.

The thickness Y1 of the transparent conductive layer 270a may be 0.03 to 0.7 times greater than the thickness X2 of the function layer 260.

A light-emitting device 200 made using the aforementioned ranges of values may therefore have good emission efficiency and uniformity of light output from a corresponding sub-pixel. Further, the light-emitting device can have small power consumption and high emission efficiency, and it is also efficient in terms of process such as etching.

In the foregoing embodiment, a hole injection layer 261 and a hole transfer layer 263 may be sequentially formed over the first electrode 250, and more specifically between the first electrode and the function layer 260. The hole injection layer and the hole transfer layer can make smooth the transfer of holes from the first electrode 250 to the emitting layer 265.

An electron transfer layer 267 may be formed on the emitting layer 265 between the emitting layer 265 and the second electrode 270. These layers can make smooth the transfer of electrons from the second electrode 270 to the emitting layer 265.

One or more of the emitting layer 265, the hole injection layer 261, the hole transfer layer 263, or the electron transfer layer 267 may be formed from an organic material or an inorganic material.

The hole injection layer 261 may also be formed from an organic material and an inorganic material. Further, the inorganic material may be a metal compound such as but not limited to an alkali metal or alkali earth metal. Examples of a metal compound comprising an alkali or alkali earth metal include LiF, NaF, KF, RbF, CsF, FrF, BeF2, MgF2, CaF2, SrF2, BaF2, or RaF2.

Generally, the mobility of holes is generally 10 times faster than the mobility of electrons. Thus, the amount of holes injected into the emitting layer 265 may be different from the amount of electrons injected into the emitting layer 265. Thus, emission efficiency may be degraded.

In accordance with the present embodiment, including an inorganic material in the hole injection layer may function to lower the highest level of a valence band of a hole injection layer, compared to a hole injection layer formed only of organic material. Thus, including an inorganic material in hole injection layer 261 also formed of organic material, will serve to lower the mobility of holes injected from the first electrode 250 to the emitting layer 265, so that the amount of holes and electrons transferred into the emitting layer is more balanced. Accordingly, there is an advantage in that emission efficiency can be improved.

One or more embodiments disclosed herein therefore provide a light-emitting device with improved emission efficiency, less power consumption, and increased process efficiency.

According to one embodiment a light-emitting device comprises a substrate comprising a thin film transistor, a insulating film disposed on the substrate and including a via hole exposing the thin film transistor, a first electrode disposed on the insulating film and connected to the thin film transistor, an emitting layer disposed on the first electrode, and a second electrode disposed on the emitting layer and including a non-conductive layer and a transparent conductive layer sequentially disposed over the emitting layer. A thickness of the first electrode is substantially 4.2 to 7.7 times greater than a thickness of the emitting layer, and a thickness of the second electrode is substantially 0.6 to 7.3 times greater than a thickness of the emitting layer.

According to another embodiment, a light-emitting device comprises a substrate including a thin film transistor, a insulating film disposed on the substrate and including a via hole exposing the thin film transistor, a first electrode disposed on the insulating film and connected to the thin film transistor a function layer including one or more of a hole injection layer, a hole transfer layer, a emitting layer, and an electron transfer layer sequentially disposed over the first electrode, and a second electrode disposed on the function layer and including a non-conductive layer and a transparent conductive layer sequentially disposed over the function layer. A thickness of the first electrode is substantially 0.6 to 0.79 times greater than that of the function layer, and a thickness of the second electrode is substantially 0.09 to 0.76 times greater than that of the function layer.

According to any of the embodiments described herein, in a case where the emitting layer emits red light, the emitting layer may include a host material including carbazole biphenyl (CBP) or 1,3-bis(carbazol-9-yl (mCP), and may be formed of a phosphorescence material including a dopant material including PlQIr(acac)(bis(1-phenylisoquinoline)acetylacetonate iridium), PQIr(acac)(bis(1-phenylquinoline)acetylacetonate iridium), PQIr(tris(1-phenylquinoline)iridium), or PtOEP(octaethylporphyrin platinum) or a fluorescence material including PBD:Eu(DBM)3(Phen) or Perylene.

In the case where the emitting layer emits red light, a highest occupied molecular orbital of the host material may range from 5.0 to 6.5 eV, and a lowest unoccupied molecular orbital of the host material may range from 2.0 to 3.5 eV. A highest occupied molecular orbital of the dopant material may range from 4.0 to 6.0 eV, and a lowest unoccupied molecular orbital of the dopant material may range from 2.4 to 3.5 eV.

In the case where the emitting layer emits green light, the emitting layer includes a host material including CBP or mCP, and may be formed of a phosphorescence material including a dopant material including Ir(ppy)3(fac tris(2-phenylpyridine)iridium) or a fluorescence material including Alq3(tris(8-hydroxyquinolino)aluminum).

In the case where the emitting layer emits green light, a highest occupied molecular orbital of the host material may range from 5.0 to 6.5 eV, and a lowest unoccupied molecular orbital of the host material may range from 2.0 to 3.5 eV. A highest occupied molecular orbital of the dopant material may range from 4.5 to 6.0 eV, and a lowest unoccupied molecular orbital of the dopant material may range from 2.0 to 3.5 eV.

In the case where the emitting layer emits blue light, the emitting layer includes a host material including CBP or mCP, and may be formed of a phosphorescence material including a dopant material including (4,6-F2 ppy)2Irpic or a fluorescence material including spiro-DPVBi, spiro-6P, distyryl-benzene (DSB), distyryl-arylene (DSA), PFO-based polymers, PPV-based polymers, or a combination thereof.

In the case where the emitting layer emits blue light, a highest occupied molecular orbital of the host material may range from 5.0 to 6.5 eV, and a lowest unoccupied molecular orbital of the host material may range from 2.0 to 3.5 eV. A highest occupied molecular orbital of the dopant material may range from 4.5 to 6.0 eV, and a lowest unoccupied molecular orbital of the dopant material may range from 2.0 to 3.5 eV.

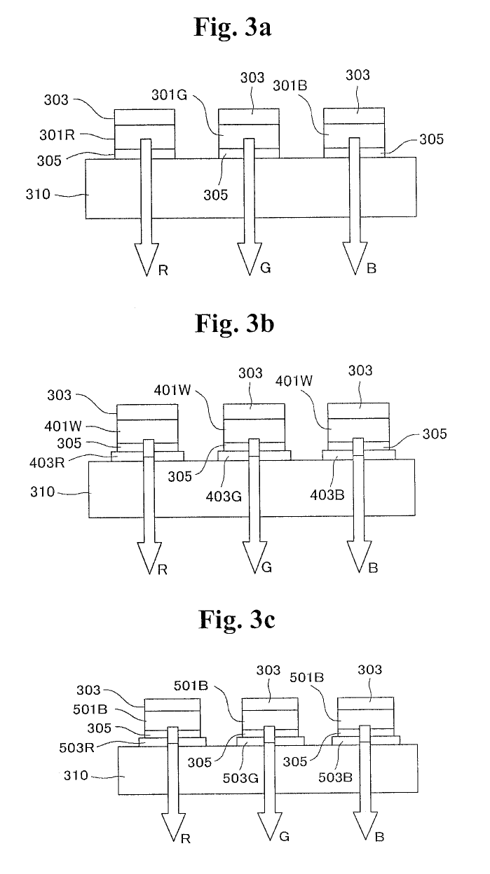

Additional embodiments relating to various color image display methods in an organic light emitting device will now be described with reference to FIGS. 3a to 3c.

FIGS. 3a to 3c illustrate various implementations of a color image display method in an organic light emitting device according to one exemplary embodiment.

First, FIG. 3a illustrates a color image display method in an organic light emitting device separately including a red organic emitting layer 301R, a green organic emitting layer 301G and a blue organic emitting layer 301B which emit red, green and blue light, respectively.

The red, green and blue light produced by the red, green and blue organic emitting layers 301R, 301G and 301B is mixed to display a color image.

It may be understood in FIG. 3a that the red, green and blue organic emitting layers 301R, 301G and 301B each include an electron transfer layer, an emitting layer, a hole transfer layer, and the like. In FIG. 3b, a reference numeral 303 indicates a cathode electrode, 305 an anode electrode, and 310 a substrate. It is possible to variously change a disposition and a configuration of the cathode electrode, the anode electrode and the substrate.

FIG. 3b illustrates a color image display method in an organic light emitting device including a white organic emitting layer 401W, a red color filter 403R, a green color filter 403G and a blue color filter 403B.

As illustrated in FIG. 3b, the red color filter 403R, the green color filter 403G and the blue color filter 403B each transmit white light produced by the white organic emitting layer 401W to produce red light, green light and blue light. The red, green and blue light is mixed to display a color image. And an organic light emitting device may further include a white color filter. So the organic light emitting device may realization various colors by manner of RIG/B or RIG/B/W

It may be understood in FIG. 3b that the white organic emitting layer 401W includes an electron transfer layer, an emitting layer, a hole transfer layer, and the like.

FIG. 3c illustrates a color image display method in an organic light emitting device including a blue organic emitting layer 501B, a red color change medium 503R and a green color change medium 503G.

As illustrated in FIG. 3c, the red color change medium 503R and the green color change medium 503G each transmit blue light produced by the blue organic emitting layer 501B to produce red light, green light and blue light. The red, green and blue light is mixed to display a color image.

It may be understood in FIG. 3c that the blue organic emitting layer 501B includes an electron transfer layer, an emitting layer, a hole transfer layer, and the like.

And a difference between driving voltages, e.g., the power voltages VDD and Vss of the light emitting device may change depending on the size of the light emitting device 100 (or 200) and a driving manner. A magnitude of the driving voltage is shown in the following Tables 1 and 2. Table 1 indicates a driving voltage magnitude in case of a digital driving manner, and Table 2 indicates a driving voltage magnitude in case of an analog driving manner.

TABLE 1

| Size (S) of display | | | |
|---|---|---|---|
| panel | VDD-Vss (R) | VDD-Vss (G) | VDD-Vss (B) |
| S < 3 inches | 3.5-10 (V) | 3.5-10 (V) | 3.5-12 (V) |
| 3 inches < S < 20 | 5-15 (V) | 5-15 (V) | 5-20 (V) |
| inches | | | |
| 20 inches < S | 5-20 (V) | 5-20 (V) | 5-25 (V) |

TABLE 2

| Size (S) of display panel | VDD-Vss (R, G, B) |
|---|---|
| S < 3 inches | 4~20 (V) |
| 3 inches < S < 20 inches | 5~25 (V) |
| 20 inches < S | 5~30 (V) |

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments of the present invention have been described with reference to a number of illustrative embodiments thereof, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses will also be apparent to those skilled in the art.

What is claimed is:

1. A light-emitting device, comprising:
a substrate including a thin film transistor;
an insulating film disposed on the thin film transistor;
a first electrode disposed on the insulating film and connected to the thin film transistor;
a emitting layer disposed on the first electrode; and
a second electrode disposed on the emitting layer and including a non-conductive layer and a transparent conductive layer sequentially disposed over the emitting layer, wherein a thickness of the first electrode is substantially 4.2 to 7.7 times greater than a thickness of the emitting layer, and a thickness of the second electrode is substantially 0.6 to 7.3 times greater than the thickness of the emitting layer.

2. The light-emitting device of claim 1, wherein the first electrode has a double-layer structure which includes a reflective electrode and a first transparent electrode, or a triple-layer structure which includes a second transparent electrode, a reflective electrode and a first transparent electrode.

3. The light-emitting device of claim 1, wherein the first electrode is an anode electrode and the second electrode is a cathode electrode.

4. The light-emitting device of claim 1, wherein the non-conductive layer includes lithium fluoride (LiF) or lithium complex (Liq).

5. The light-emitting device of claim 1, wherein at least one of a hole injection layer or a hole transfer layer are further disposed on the first electrode between the first electrode and the emitting layer.

6. The light-emitting device of claim 1, wherein an electron transfer layer is further disposed between the emitting layer and the non-conductive layer.

7. The light-emitting device of claim 5, wherein at least one of the emitting layer, hole injection layer or hole transfer layer include at least one of an organic material or an inorganic material.

8. The light-emitting device of claim 6, wherein the electron transfer layer includes an organic material or an inorganic material.

9. The light-emitting device of claim 1, wherein a thickness of the transparent conductive layer is substantially 0.2 to 6.7 times greater than the thickness of the emitting layer.

10. The light-emitting device of claim 7, wherein the hole injection layer includes the organic material and the inorganic material.

11. The light-emitting device of claim 1, wherein the emitting layer includes at least one of a fluorescence material or a phosphorescence material.

12. The light-emitting device of claim 1, wherein the insulating film corresponds to or includes a planarization film.

13. A light-emitting device, comprising:
a substrate including a thin film transistor;
a insulating film disposed on the thin film transistor;
a first electrode disposed on the insulating film and connected to the thin film transistor;
a function layer including at least one of a hole injection layer, a hole transfer layer, a emitting layer, or an electron transfer layer sequentially disposed over the first electrode; and
a second electrode disposed on the function layer and including a non-conductive layer and a transparent conductive layer sequentially disposed over the function layer, wherein a thickness of the first electrode is substantially 0.6 to 0.79 times greater than a thickness of the function layer, and wherein a thickness of the second electrode is substantially 0.09 to 0.76 times greater than the thickness of the function layer.

14. The light-emitting device of claim 13, wherein the first electrode has a double-layer structure which includes a reflective electrode and a first transparent electrode, or a triple-layer structure which includes a second transparent electrode, a reflective electrode and a first transparent electrode.

15. The light-emitting device of claim 13, wherein the first electrode is an anode electrode and the second electrode is a cathode electrode.

16. The light-emitting device of claim 13, wherein the non-conductive layer includes lithium fluoride (LiF) or lithium complex (Liq).

17. The light-emitting device of claim 13, wherein at least one of the emitting layer, hole injection layer, hole transfer layer, or electron transfer layer includes at least one of an organic material or an inorganic material.

18. The light-emitting device of claim 13, wherein a thickness of the transparent conductive layer is substantially 0.03 to 0.7 times greater than the thickness of the function layer.

19. The light-emitting device of claim 17, wherein the hole injection layer includes the organic material and the inorganic material.

20. The light-emitting device of claim 13, wherein the insulating film corresponds to or includes a planarization film.

21. A light-emitting device, comprising:
a substrate including a thin film transistor;
an insulating film disposed on the thin film transistor;
a first electrode disposed on the insulating film and connected to the thin film transistor;
a emitting layer disposed on the first electrode; and
a second electrode disposed on the emitting layer and including a non-conductive layer and a transparent conductive layer sequentially disposed over the emitting layer, wherein a thickness of the first electrode is substantially 4.2 to 7.7 times greater than a thickness of the emitting layer, and a thickness of the second electrode is substantially 0.6 to 7.3 times greater than a thickness of the emitting layer,
wherein at least one of a hole injection layer or a hole transfer layer is disposed between the first electrode and the emitting layer, the hole injection layer including at least one of an organic material or an inorganic material, and
wherein a highest level of a valence band of the hole injection layer including the inorganic material is smaller than a highest level of a valence band of the hole injection layer that includes the organic material without the inorganic material.

22. A light-emitting device, comprising:
a substrate including a thin film transistor;
a insulating film disposed on the thin film transistor;
a first electrode disposed on the insulating film and connected to the thin film transistor;
a function layer including one or more of a hole injection layer, a hole transfer layer, a emitting layer, or an electron transfer layer sequentially disposed over the first electrode; and
a second electrode disposed on the function layer and including a non-conductive layer and a transparent conductive layer sequentially disposed over the function layer, wherein a thickness of the first electrode is substantially 0.6 to 0.79 times greater than a thickness of the function layer, and wherein a thickness of the second electrode is substantially 0.09 to 0.76 times greater than the thickness of the function layer, and
wherein the hole injection layer includes at least one of an organic material or an inorganic material, and wherein a highest level of a valence band of the hole injection layer including the inorganic material is smaller than a highest level of a valence band of the hole injection layer that includes the organic material without the inorganic material.
